(19) United States
(12) Patent Application Publication
(10) Pub. No.: US 2010/0258814 A1
(43) Pub. Date: Oct. 14, 2010

(54) Light emitting diode and method of fabrication thereof

(75) Inventors: Shinichi Hoshi, Tokyo (JP); Isao Tamai, Gunma (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 12/662,317

(22) Filed: Apr. 9, 2010

(30) Foreign Application Priority Data
Apr. 13, 2009 (JP) 2009-096621

(51) Int. Cl. H01L 33/12; H01L 33/00; H01L 33/30

(52) U.S. Cl. 257/76; 438/47; 257/94; 257/E33.005; 257/E33.023

(57) ABSTRACT

There is provided a light emitting diode fabricating method including: a) forming, on a substrate and via a buffer layer, an epitaxial growth layer that includes a light emitting layer, and forming one electrode on a surface of the epitaxial growth layer; b) joining a supporting substrate to the one electrode; c) removing, by etching, the substrate and the buffer layer; and d) forming another electrode at a region, other than a region where output light is taken-out, at a reverse surface opposite the surface of the epitaxial growth layer on which the one electrode is formed.

### CROSS-REFERENCE TO RELATED APPLICATION

This application is based on and claims priority under 35 USC 119 from Japanese Patent Application No. 2009-096621 filed on Apr. 13, 2009, the disclosure of which is incorporated by reference herein.

### BACKGROUND

1. Technical Field

The present invention relates to a light emitting diode and a method of fabrication thereof, and in particular, relates to a gallium nitride type light emitting diode having a supporting substrate whose thermal conductivity is high and whose electric conductivity is high, and to a method of fabrication thereof.

2. Related Art

Most gallium nitride type light emitting diodes (also called GaN based LEDs hereinbelow) are formed on a sapphire substrate whose thermal conduction is extremely low. The thermal conductivity of sapphire crystals is 0.3 W/(cm K). Therefore, there are problems such as it is difficult for a GaN based LED that is formed on a sapphire substrate to effectively dissipate heat, and the light emitting efficiency deteriorates due to a rise in temperature during operation of the element, and the like.

On the other hand, there is also known a method of forming, by an epitaxial growing technique, a GaN based LED on a silicon substrate (Si substrate) whose impurity concentration is lower than that of a sapphire substrate and whose crystal defect density is very low (see, for example, Document 1 listed below, page 208). The thermal conductivity of Si crystals is 1.5 W/(cm K), which is five times that of sapphire crystals. Therefore, because a GaN based LED that is formed on an Si substrate can carry out effective heat dissipation, problems with the light emitting efficiency and the like, that accompany an increase in temperature of the elements, are resolved.

However, there is a great difference in the magnitudes of the lattice constants of Si crystals and GaN crystals (a mismatch of 17%). Further, the difference in the coefficients of thermal expansion of Si crystals and GaN crystals is 37%. Therefore, in order to epitaxially grow a GaN layer on an Si substrate with high quality, there is a technique of forming an AlGaN/AlN intermediate layer or an AlN/GaN multilayer buffer layer on the Si substrate, and then forming the GaN epitaxial growth layer.

Here, an AlGaN/AlN intermediate layer means a layer by epitaxially growing an AlGaN layer on the main surface of an Si substrate, and subsequently forming an AlN epitaxial growth layer. Further, an AlN/GaN multilayer buffer layer means a buffer layer that is formed as a multilayer structure by epitaxially growing and layering an AlN layer and a GaN layer alternately in multiple layers.

It is known that, when a GaN layer is epitaxially grown directly on the main surface of an Si substrate, the Ga atoms are diffused in the Si substrate, and a carrier deposition layer is formed. This carrier deposition layer affects the frequency response characteristics and the like of the electronic elements such as the LEDs and the like that are formed on the Si substrate, and, depending on'the case, problems may arise in the characteristics that are required of the elements. Thus, in order to prevent this diffusion of Ga atoms into the Si substrate, a technique is used of first epitaxially growing an AlN nucleation layer on the main surface of the Si substrate.

Document 1: LED2008, “New Developments in Techniques and Application”, Nikkei Business Publications, Inc., pp. 8-19, pp. 124-133, pp. 200-209

Document 2: Egawa Takashi, “Research Activities of the Organic Metal Vapor Phase Growth Technology (Taiyo Nippon Sanso Corporation) Endowed Research Department, Nagoya Institute of Technology”

Document 3: Suga et al., “Low-Temperature Joining by Surface Activation for Next-Generation High-Density Packaging”, Ultra-High-Function Global Integration Research Society Lecture Proceedings, (2003), pp. 185-188 (search results of Mar. 19, 2009), internet:

“URL:http://masu-www.pi.titech.ac.jp/˜global/pub/2003_{—}0301_{—}0302_yokou_web/su ga.pdf”.

Here, in order to clarify the problems that are to be solved by the present invention, the rough structure of a conventional GaN based LED that is formed by using an Si substrate, and a summary of the method of fabrication thereof, are described with reference to FIG. 1A through FIG. 3B. Note that, in FIG. 1A through FIG. 3B, similar structural elements are denoted by the same numerals, and redundant description thereof may be omitted.

First, the structure of an epitaxial growth layer for fabricating a GaN based LED is described with reference to FIG. 1A through FIG. 1C. FIG. 1A through FIG. 1C are drawings provided for explanation of the structure of the epitaxial growth layer for fabricating a GaN based LED that is formed on an Si substrate. The substrate, that is used in order to fabricate the GaN based LED and that includes an Si substrate and the epitaxial growth layer for fabricating the GaN based LED that is formed on the Si substrate, is also called a GaN-LED on Si substrate hereinbelow. FIG. 1A is a schematic overall view of a GaN-LED on Si substrate. FIG. 1B is an enlarged drawing of an epitaxial growth layer portion that structures the basic structure of the LED at the time of being processed as an LED. FIG. 1C is an enlarged drawing of a portion of a buffer layer that is layered on the Si substrate.

As shown in FIG. 1A through FIG. 1C, at the GaN-LED on Si substrate, an AlN•nucleation layer 12-1 of a thickness of 100 nm and a UID-AlGaN layer 12-2 of a thickness of 40 nm are layered as a buffer layer 12 on an n-type Si substrate 10. A multilayer buffer layer 14 in which 40 sets of a set, that is a GaN layer and an AlN layer, are repeatedly layered, is formed on the buffer layer 12. The thicknesses of the GaN layer and the AlN layer that form the multilayer buffer layer 14 are 20 nm and 5 nm, respectively. Following the multilayer buffer layer 14, an n-type GaN layer 16 of a thickness of 1 μm is formed.

Here, the “UID” of the UID-AlGaN layer and the like is an abbreviation of Un-Intentionally Doped, and means that, although intentional doping is not carried out, residual carrier of around 10¹⁷/cm⁻³ exists.

A UID-GaN layer 20-1 that is a thickness of 25 nm, an InGaN layer (also called InGaN light emitting layer) 20-2 that is a thickness of 3 nm and is a light emitting layer at the time of being structured as an LED, a UID-GaN layer 20-3 that is a thickness of 25 nm, a p-type AlGaN layer 20-4 that is a thickness of 10 nm, and a p-type GaN layer 20-5 that is a thickness of 150 nm, are layered and formed as an epitaxial growth layer 20, successively after the n-type GaN layer 16.

FIG. 1A through FIG. 1C show the structure of a GaN-LED on Si substrate that is premised on forming an LED. However, when fabricating a GaN based laser diode (hereinafter abbreviated as GaN based LD), it suffices for there to be a structure in which the InGaN layer 20-2 is used as an active layer (a laser active medium) and the InGaN layer 20-2 is sandwiched by cladding layers that are formed from p-type InGaN and n-type InGaN based mixed crystals whose band gap is wider than and whose refractive index is lower than those of the InGaN layer 20-2. The oscillation characteristic of an LD strongly depends on the temperature in the vicinity of the p-n junction surface that includes the p-n junction surface that exists within the active layer that is the InGaN layer 20-2, and therefore, carrying out heat dissipation effectively is particularly important.

A GaN based LD also is one particular structure of a GaN based LED to which a light feedback structure is mounted. Because mounting a light feedback structure is possible by using known techniques, here, a GaN based LED will be described without discussion of the light feedback structure. Namely, it is to be understood that GaN based LDs fall within the purview of GaN based LEDs that are the higher concept.

In FIG. 1A through FIG. 1C, the UID-GaN layer 20-1, the InGaN layer 20-2, the UID-GaN layer 20-3, the p-type AlGaN layer 20-4, and the p-type GaN layer 20-5 are illustrated collectively as the epitaxia1 growth layer 20, and the epitaxial growth layer 20 and the n-type GaN layer 16 are illustrated collectively as an LED epitaxial growth layer 40-2. Further, the buffer layer 12 and the multilayer buffer layer 14 are illustrated collectively as a buffer layer 40-1. The buffer layer 40-1 and the LED epitaxial growth layer 40-2 are illustrated collectively as an epitaxial growth layer 40. Hereinafter, the LED epitaxial growth layer 40-2 is also called a light emitting region epitaxial growth layer that includes the InGaN light emitting layer 20-2.

Next, the structure of a GaN based LED, that is structured by using a representative GaN-LED on Si substrate, is described with reference to FIGS. 2A and 2B. FIGS. 2A and 2B are schematic sectional structural drawings of a GaN based LED that is structured by using a GaN-LED on Si substrate. FIG. 2A is a schematic overall view of the LED. FIG. 2B is an enlarged drawing that includes an n side electrode 22 and a p side electrode 24 of a portion that structures the basic structure of the LED at the time of being processed as an LED.

As shown in FIGS. 2A and 2B, the buffer layer 12 and the multilayer buffer layer 14, that are for epitaxially growing the n-type GaN layer 16 by using the n-type Si substrate 10, are electrically high resistance layers. This is because the forbidden bandwidth of AlN crystals is 6.2 eV which is large. Formation of the p side and n side electrodes, that are for injecting current to the p-n junction existing within the InGaN light emitting layer 20-2, by sandwiching the buffer layer 12 and the multilayer buffer layer 14, is avoided. As shown in FIG. 2B, the n side electrode 22 is provided on a top surface 16a of the n-type GaN layer 16, and the p side electrode 24 is provided on a top surface 20a of the p-type GaN layer 20-5.

However, the LED of the structure shown in FIGS. 2A and 2B is a structure in which the n side electrode 22 and the p side electrode 24 are both provided at the side at which the light is taken-out. Therefore, it is difficult to make the surface area of the region for taking-out light be large. Thus, a particular contrivance is needed in order to take-out light efficiently (refer to Document 1, page 15, FIG. 18(b)).

Thus, the structure of a GaN based LED, that is structured by using a GaN-LED on Si substrate and at which the surface area of the region for taking-out light can be made to be large, is examined. The structure of a GaN based LED, at which the surface area of the region for taking-out light can be made to be large, is described with reference to FIG. 3A and FIG. 3B. FIGS. 3A and 3B are schematic sectional structural drawings of a GaN based LED that is structured by using a GaN-LED on Si substrate and at which the surface area of the region for taking-out light can be made to be large. FIG. 3A is a schematic overall view of the LED, and FIG. 3B is an enlarged drawing of the buffer layer 12.

In order to make the surface area of the region for taking-out light be large, a structure in which the n side electrode and the p side electrode are both provided at the side at which light is taken-out is avoided. As shown in FIG. 3A, a structure is proposed in which an n side electrode 32 is provided at a surface 10a, of the n-type Si substrate 10, that is at the side opposite the surface at which the epitaxial growth layer 40 is formed, and a p side electrode 30 is provided at the top surface 20a of the epitaxial growth layer 20.

However, in this structure, although the surface area of the region for taking-out light can be made to be large, the current, that is injected into the p-n junction that exists within the InGaN light emitting layer 20-2 as described above, flows via the buffer layer 12 and the multilayer buffer layer 14 that are electrically high resistance layers. Therefore, heat is generated at the buffer layer 12 and the multilayer buffer layer 14 as well. Thus, it is difficult to suppress a rise in temperature of the InGaN light emitting layer 20-2, and it is difficult to realize an LED having a high light emitting efficiency (refer to Document 2 for example).

Document 2 reports that the operating voltage and the resistance value of an LED formed by using a sapphire substrate are 3.3 V and 25 Ω respectively, whereas the operating voltage and the resistance value of an LED formed by using the Si substrate of the structure shown in FIGS. 3A and 3B are 4.1 V and 30 Ω respectively. The operating voltage and the resistance value of an LED formed by using the Si substrate are both greater than those of an LED formed by using a sapphire substrate. Namely, this shows that an LED, that is formed by using the Si substrate of the structure shown in FIGS. 3A and 3B, is not an LED having a high light emitting efficiency.

### SUMMARY

The inventors of the present invention diligently studied whether a GaN based LED could be made to be a structure in which the buffer layer 12 and the multilayer buffer layer 14 (the buffer layer 40-1), that are electrically high resistance layers, are eliminated, and could be made to be a structure in which the surface area of the region for taking-out light is made to be large. As a result, the inventors of the present invention confirmed that such a GaN based LED is realized if it is possible to employ a method in which, after forming the epitaxial growth layer 40 by using a GaN-LED on Si substrate, the LED epitaxial growth layer 40-2 is kept and the n-type Si substrate 10 and the buffer layer 40-1 are removed, and the n-type Si substrate 10 and the buffer layer 40-1 are replaced by a material whose thermal conductivity is high and whose electric conductivity is high.

Thus, an object of the present invention is to provide a GaN based LED and a method of fabrication thereof that, in a GaN based LED that is fabricated by using a GaN-LED on Si substrate, remove the n-type Si substrate and the buffer layer, and provide, instead of the n-type Si substrate and the buffer layer, a supporting substrate of a material having high thermal conductivity and a high electric conductivity, and further, can make the surface area of the region for taking-out light be large.

In accordance with the gist of the present invention that is based on the above-described idea, there are provided a method of fabricating a GaN based LED of the following structure, and a GaN based LED that is fabricated by this method.

The LED fabricating method of the present invention is structured to include first through fourth steps. The first step is a step of forming, on a substrate and via a buffer layer, an epitaxial growth layer that includes a light emitting layer, and forming one electrode on a surface of the epitaxial growth layer. The second step is a step of joining a supporting substrate to the one electrode. The third step is a step of removing, by etching, the substrate and the buffer layer. The fourth step is a step of forming another electrode at a region, other than a region where output light is taken-out, at a reverse surface opposite the surface, on which the one electrode is formed, of the epitaxial growth layer.

It is suitable to make the second step be a step that is carried out by a surface-activated room-temperature bonding joining method that joins a surface of the one electrode and a surface of the supporting substrate by a surface activating treatment that puts atoms of the surfaces into an active state in which chemical bonds form easily.

Further, it is suitable to make the first step be a step of forming, on an n-type Si substrate, the buffer layer that includes an AlN nucleation layer, an AlGaN layer and a GaN/AlN multilayer buffer layer, and an n-type GaN layer, and the epitaxial growth layer that includes an InGaN light emitting layer, and forming a p side electrode on the surface of the epitaxial growth layer, and to make the second step be a step of joining the supporting substrate to the p side electrode that is the one electrode, and to make the third step be a step of removing, by etching, the n-type Si substrate and the buffer layer, and to make the fourth step be a step of forming an n side electrode at a region, other than a region where output light is taken-out, at a reverse surface opposite a surface, of the n-type GaN layer, which surface is at a side where the epitaxial growth layer including the InGaN light emitting layer is formed.

In the second step, it is good to make the supporting substrate be an AlN sintered supporting substrate. Or, it is good to make the supporting substrate be a copper supporting substrate. Or, it is good to use an AlN sintered supporting substrate, in which via holes are formed, as the AlN sintered supporting substrate.

The LED of the present invention can be fabricated in accordance with the above-described LED fabricating method of the present invention.

The LED of the present invention includes: an epitaxial growth layer that includes a light emitting layer; and a supporting substrate joined to a surface of an electrode formed at the epitaxial growth layer.

It is suitable to make the LED of the present invention be a structure in which the light emitting layer is an InGaN light emitting layer, and the epitaxial growth layer is structured from an epitaxial growth layer that includes an n-type GaN layer and the InGaN light emitting layer, and a p side electrode is formed one reverse surface opposite a surface, of the n-type GaN layer, which surface is at a side where output light is taken-out, and the p side electrode and the supporting substrate are joined by surface-activated room-temperature bonding joining, and an n side electrode is formed at a region, other than a region where the output light is taken-out, of the surface of the n-type GaN layer at the side where the output light is taken-out.

It is good to make the supporting substrate be an AlN sintered supporting substrate or a copper supporting substrate. Further, it is good to make the supporting substrate be an AlN sintered supporting substrate in which via holes are formed.

In accordance with the LED fabricating method of the present invention, the supporting substrate, whose thermal conductivity is high and whose electric conductivity is greater than those of the n-type Si substrate and the buffer layer, is joined in the second step to the one electrode by the surface-activated room-temperature bonding joining method. Further, in the third step, the n-type Si substrate and the buffer layer are removed by etching.

In an LED that is formed by using a GaN-LED on Si substrate, the substrate is an n-type Si substrate. Accordingly, the n-type Si substrate and the buffer layer are removed in the third step. Namely, the LED that is fabricated by the LED fabricating method of the present invention does not have an Si substrate or a buffer layer in the stage in which the LED is completed.

Further, if an AlN sintered supporting substrate or a copper supporting substrate is used as the supporting substrate, these substrates have high thermal conductivities, and the electric conductivities thereof are greater than those of an n-type Si substrate and a buffer layer. Accordingly, even if the p side electrode and the n side electrode are formed so as to sandwich this supporting substrate, the amount of heat generated due to current flowing through the supporting substrate can be made to be sufficiently small.

Namely, in accordance with the LED fabricating method of the present invention, it is possible to form a structure in which only one of the n side electrode and the p side electrode is provided at the side at which light is taken-out, and the other electrode is provided at the opposite side surface with the supporting substrate therebetween. Due thereto, it suffices to provide only one electrode at the side at which light is taken-out, and therefore, the surface area of the region for taking-out light can be made to be large.

By using an AlN sintered supporting substrate as the supporting substrate, the thermal expansion coefficient of the AlN sintered supporting substrate and the thermal expansion coefficient of the epitaxial growth layer that includes the light emitting layer are substantially equal. Therefore, a heat treatment, for realizing ohmic contact at the time of forming the p side electrode and the n side electrode, can be carried out at a high temperature of several hundred degrees C. Therefore, because there is no need to dope, at a high concentration, the epitaxial growth layer at which the electrode is formed, an epitaxial growth layer having high crystal quality (a low concentration of lattice defects) can be formed.

When an AlN sintered supporting substrate is used as the supporting substrate, if via holes are formed in the AlN sintered supporting substrate, the thermal conductivity becomes even higher. Therefore, the heat dissipating effect is great, a rise in temperature of the light emitting layer is suppressed, and an LED having high light emitting efficiency can be realized.

### BRIEF DESCRIPTION OF THE DRAWINGS

An exemplary embodiment of the present invention will be described in detail based on the following figures, wherein:

FIG. 1A is a drawing provided for explanation of the structure of an epitaxial growth layer for fabricating a GaN based LED that is formed on an Si substrate, and in particular, is an overall view of a GaN-LED on Si substrate;

FIG. 1B is a drawing provided for explanation of the structure of the epitaxial growth layer for fabricating the GaN based LED that is formed on the Si substrate, and in particular, is an enlarged view of an epitaxial growth layer portion that structures the basic structure of the LED at the time of being processed as an LED;

FIG. 1C is a drawing provided for explanation of the structure of the epitaxial growth layer for fabricating the GaN based LED that is formed on the Si substrate, and in particular, is an enlarged view of a portion of a buffer layer that is layered on the Si substrate;

FIG. 2A is a schematic sectional structural drawing of a GaN based LED structured by using a GaN-LED on Si substrate, and in particular, is a schematic overall view of the LED;

FIG. 2B is a schematic sectional structural drawing of the GaN based LED structured by using the GaN-LED on Si substrate, and in particular, is an enlarged view including an n side electrode and a p side electrode of a portion that structures the basic structure of the LED at the time of being processed as an LED;

FIG. 3A is a schematic sectional structural view of a GaN based LED that is structured by using a GaN-LED on Si substrate at which the surface area of a region for taking-out light can be made to be large, and in particular, is a schematic overall view of the LED;

FIG. 3B is a schematic sectional structural view of the GaN based LED that is structured by using the GaN-LED on Si substrate at which the surface area of the region for taking-out light can be made to be large, and in particular, is an enlarged view of a buffer layer;

FIG. 4A is a drawing provided for explanation of an LED fabricating method of an exemplary embodiment of the present invention, and in particular, is a drawing provided for explanation of a first step;

FIG. 4B is a drawing provided for explanation of the LED fabricating method of the exemplary embodiment of the present invention, and in particular, is a drawing provided for explanation of a second step;

FIG. 4C is a drawing provided for explanation of the LED fabricating method of the exemplary embodiment of the present invention, and in particular, is a drawing provided for explanation of a third step;

FIG. 4D is a drawing provided for explanation of the LED fabricating method of the exemplary embodiment of the present invention, and in particular, is a drawing provided for explanation of a fourth step; and

FIG. 5 is a drawing showing the sectional structure of the LED of the exemplary embodiment of the present invention.

### DETAILED DESCRIPTION

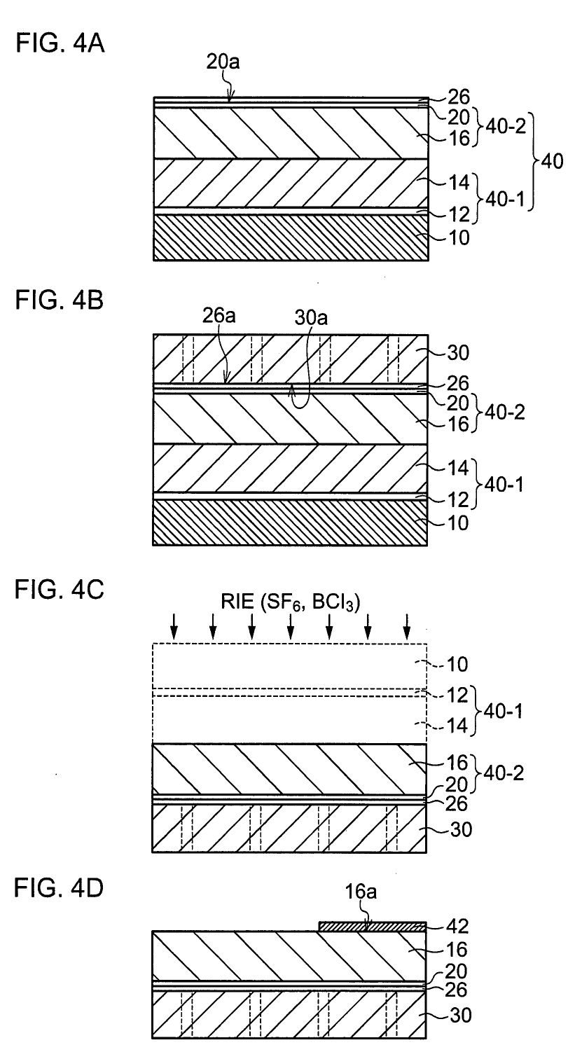

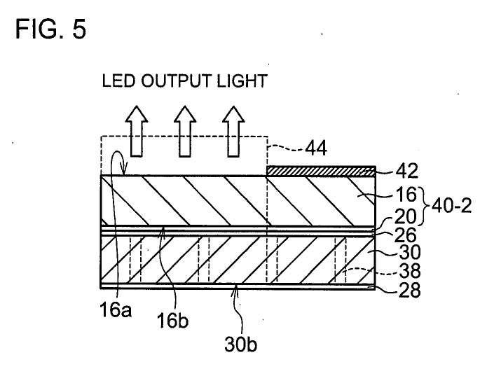

An exemplary embodiment of the present invention will be described hereinafter with reference to FIGS. 4A through 4D and FIG. 5. Note that FIGS. 4A through 4D and FIG. 5 illustrate a structural example relating to the present invention, and merely show the respective epitaxial growth layers and the like schematically to the extent that the present invention can be understood, but the present invention is not limited to the illustrated example. Further, although specific conditions and the like are utilized in the following description, these conditions and the like are merely ones of suitable examples, and accordingly, the present invention is not limited by these in any way. Moreover, similar structural elements in FIG. 4 and FIG. 5 are denoted by the same numerals, and redundant description thereof may be omitted.

<Method of Fabricating the LED of the Exemplary Embodiment of the Present Invention>

A method of fabricating an LED of an exemplary embodiment of the present invention, that uses a GaN-LED on Si substrate, is described with reference to FIGS. 4A through 4D. FIGS. 4A through 4D are drawings provided for explanation of the method of fabricating the LED of the exemplary embodiment of the present invention.

FIG. 4A is a drawing provided for explanation of a first step that forms, on the n-type Si substrate 10, the buffer layer 40-1 that includes the AlN nucleation layer 12-1, the UID-AlGaN layer 12-2 and the GaN/AlN multilayer buffer layer 14, and the epitaxial growth layer (hereinafter called the LED epitaxial growth layer 40-2) that includes the n-type GaN layer 16 and the InGaN light emitting layer 20-2, and forms a p side electrode 26 on the surface 20a (the surface of the p-type GaN layer 20-5 that will be described later) of the LED epitaxial growth layer 20-2. FIG. 4A shows the AlN nucleation layer 12-1 and the UID-AlGaN layer 12-2 collectively as the buffer layer 12. The aforementioned light emitting region is described below as a light emitting region 44 with reference to FIG. 5.

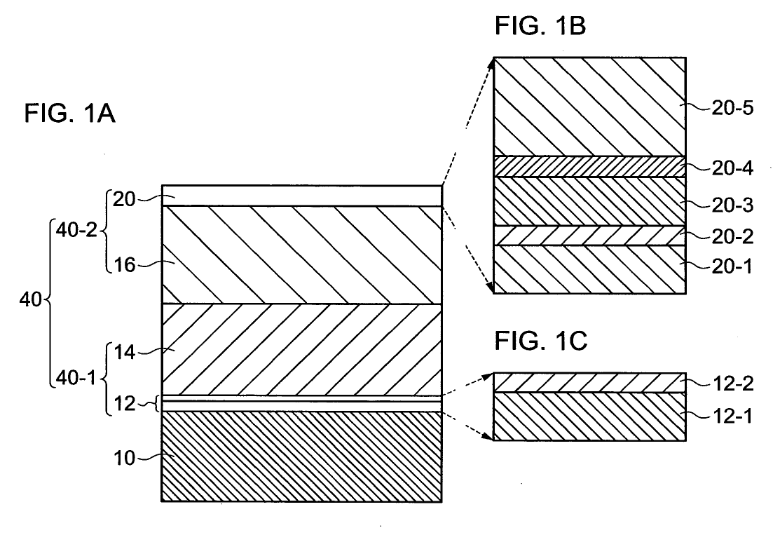

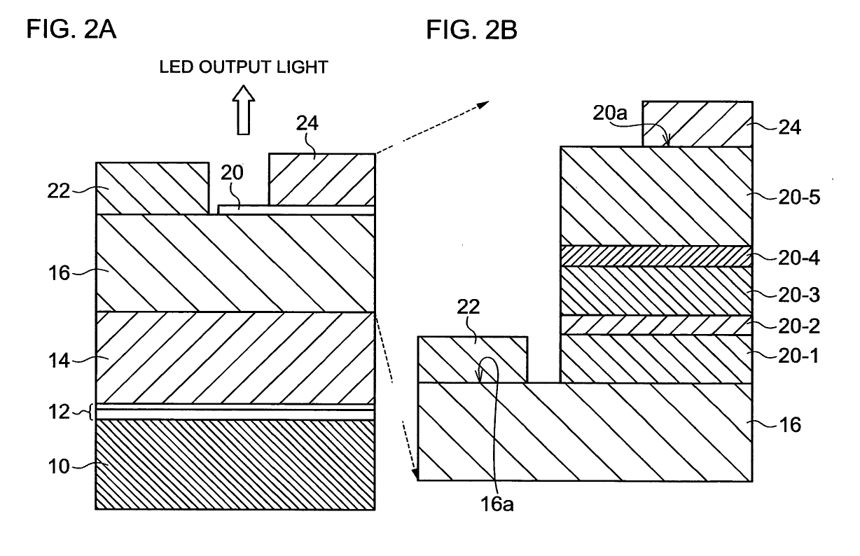

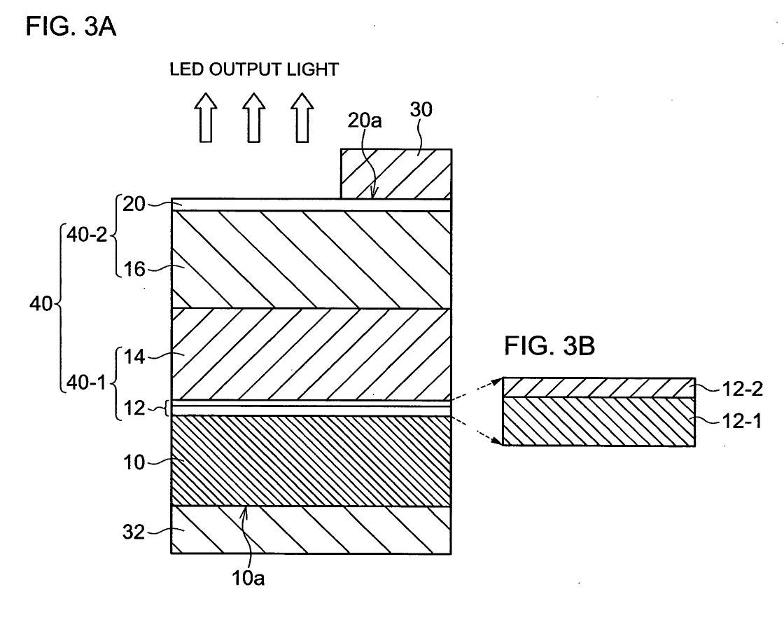

As described with reference to FIGS. 1A through 1C, the epitaxial growth layer 40 is an epitaxial growth layer formed from the buffer layer 40-1 and the LED epitaxial growth layer 40-2. The buffer layer 40-1 is formed from the buffer layer 12 and the multilayer buffer layer 14. The LED epitaxial growth layer 40-2 is formed from the epitaxial growth layer 20 and the n-type GaN layer 16. Further, the epitaxial growth layer 20 is formed from the UID-GaN layer 20-1, the InGaN layer 20-2, the UID-GaN layer 20-3, the p-type AlGaN layer 20-4, and the p-type GaN layer 20-5.

The epitaxial growth step that forms the epitaxial growth layer 40 having the buffer layer 40-1 and the LED epitaxial growth layer 40-2 can be implemented by a conventionally known method such as MOCVD or the like, and therefore, detailed description thereof is omitted here.

The topmost surface of the epitaxial growth layer 40 means the surface 20a of the aforementioned p-type GaN layer 20-5. Namely, the p side electrode 26 is formed on the surface 20a. The p side electrode 26 can be formed by a known method such as vacuum vapor deposition or the like, and ohmic contact is realized by heat treatment after the vacuum vapor deposition. A metal vapor deposited thin film, that is formed by vacuum vapor depositing a metal, can be used as the p side electrode 26.

FIG. 4B is a drawing provided for explanation of a second step of joining a supporting substrate 30 to the p-side electrode 26. This second step is a joining step that is carried out by a surface-activated room-temperature bonding joining method that joins a surface 26a of the p side electrode 26 and a surface 30a of the supporting substrate 30 by a surface activating treatment that sets the surface 26a and the surface 30a in active states in which chemical bonds form easily.

The surface-activated room-temperature bonding joining method is a technique of irradiating a high-speed atomic beam or high-frequency plasma onto both surfaces that are to be joined so as to clean/activate the surfaces to be joined, and joining the both surfaces together by causing the both surfaces to contact one another at ordinary temperature (see, for example, Document 3).

In carrying out the surface-activated room-temperature bonding joining, first, the both surfaces to be joined are cleaned. However, in the atmosphere, the surface is, substantially instantaneously after cleaning, covered by an oxide film due to oxygen or by molecules of water or organic substances that adsorb, or the like. In this way, even if joining is aimed for by causing the surfaces, that are covered by oxide films or the like in this way, to contact one another, a sufficient bonding force cannot be brought about. Therefore, both surfaces to be joined are cleaned in a vacuum, and the both surfaces are made to contact one another and are joined together in states of not being covered by oxide films or the like. Here, the degree of vacuum is preferably made to be a high vacuum of 10⁻⁶ to 10⁻⁸ Pa (pascals).

Here, an AIN sintered body substrate is used as the supporting substrate 30. The both surfaces to be joined, that are the surface 26a of the p side electrode 26 and the surface 30a of the AlN sintered body substrate, are cleaned by a method of irradiating Ar radicals onto the cleaning surfaces in a high vacuum, and thereafter, by causing the surface 26a and the surface 30a to contact one another, the both surfaces are joined together at ordinary temperature. By irradiating Ar radicals onto the surface 26a and the surface 30a that are to be cleaned, impurities, oxides and the like that adsorb at these surfaces are removed by the Ar radicals, and the surfaces are set in activated states.

Here, a condition that is important in the joining at ordinary temperature is that both the micro planarity and the macro planarity of the both surfaces to be joined are small. The micro planarities of the both surfaces were investigated by an atomic force microscope (AFM), and the macro planarities were investigated by a wafer warpage meter. As a result, it was found that both the GaN-LED on Si substrate and the AlN sintered body substrate had a micro planarity of less than or equal to 1 nm as a root mean square roughness of 1 μm square, and that the magnitude of the wafer warpage that is the macro planarity was less than or equal to 20 μm at a substrate of a diameter of three inches. Namely, it was confirmed that both the GaN-LED on Si substrate and the AlN sintered body substrate had the planarities needed for joining at ordinary temperature.

The difference in the thermal expansion coefficients of the AlN sintered body substrate and the GaN layer portion of the GaN-LED on Si substrate is small. Therefore, strain (stress) to the extent of causing problems, such as cracks arising in the crystals or the like, does not occur at the interface between the both due to the heat treatment that is carried out after the joining at ordinary temperature.

Here, an AlN sintered body substrate is used as the supporting substrate 30, but a copper substrate can be used. A copper substrate has an excellent heat-dissipating characteristic, and the thermal expansion coefficient of copper is 1.409×10⁻⁵/K. The thermal expansion coefficient of GaN crystals is 5.59×10⁻⁶/K. Therefore, there is a difference of 250% between the both. Thus, in order to avoid generation of stress due to thermal expansion, a heat treatment for realizing ohmic contact of the n side electrode that is described below cannot be carried out. Accordingly, when using a copper substrate as the supporting substrate 30, high-concentration doping of around 10²⁰ cm⁻³ is required at the n-type GaN layer 16 in order for ohmic contact to be realized merely by vapor depositing the n side electrode.

FIG. 4C is a drawing provided for explanation of the third step of removing, by etching, the n-type Si substrate 10 and the buffer layer 40-1.

The n-type Si substrate 10 can be etched and removed by a known method such as reactive ion etching (RIE) or the like. Here, RIE is a method of etching a sample by applying electromagnetic waves or the like to etching gas (SF₆ type gas and BCl₃ or the like) in a reaction chamber so as to change the gas into plasma, and simultaneously, applying high frequency voltage to cathodes at a side where the sample is placed. Namely, this is a dry etching method using the principle that, when high frequency voltage is applied, the ion species and radical species within the plasma are accelerated in the material direction and collide, and spattering due to the ions and a chemical reaction of the etching gas occur simultaneously, and the sample is thereby etched.

In the n-type Si substrate removal step, using a method, in which the n-type Si substrate 10 is polished and made to be thin in advance so as to become a thickness of 10 to 50 μm and is subjected to etching processing, is advantageous in terms of improving the work efficiency.

In the processing by RID in the n-type Si substrate removal step, in order to reduce the effects of damage due to etching of the n-type GaN layer 16 that structures the LED epitaxial growth layer 40-2 (damage that is received due to the ion species and radical species within the plasma being accelerated in the sample direction and colliding), the high frequency power must be made to be a proper value. For example, when using reactive ion etching that uses inductive coupled plasma (ICP-RIE), it is understood that it is suitable to carry out etching under the conditions that the ICP power is 50 W, the RIE power is 10 W, and the etching rate of the GaN crystal layer is 3 nm/minute.

If the n-type GaN layer 16 that structures the LED epitaxial growth layer 40-2 is damaged by etching, it becomes difficult to realize ohmic contact between the n-type GaN layer 16 and an n side electrode 42 that is formed in the fourth step that is described below. Therefore, the interface between the n side electrode 42 and the n-type GaN layer 16 becomes a high electrical resistance layer, and there is the possibility of heat generation at this interface during operation of the LED. Accordingly, as mentioned above, it is important to keep the etching damage to the n-type GaN layer 16 as small as possible.

In the third step, in removing the n-type Si substrate 10 and the buffer layer 40-1 by etching, there is no difference in the etching speeds of the buffer layer 40-1 and the LED epitaxial growth layer 40-2. Therefore, etching time control must be carried out such that, when the etching of the multilayer buffer layer 14 that structures the buffer layer 40-1 is finished, etching processing is ended immediately before the n-type GaN layer 16 that structures the LED epitaxial growth layer 40-2 is etched.

For this etching time control, the etching rate can be measured in advance by using a substrate of a structure that is similar to a GaN-LED on Si substrate. Further, the etching rate is also low in relation to keeping the high frequency power of the RIE low, in order to as much as possible not inflict etching damage on the n-type GaN layer 16 as mentioned above. Accordingly, etching time control can be carried out precisely.

FIG. 4D is a drawing provided for explanation of the fourth step of forming the n side electrode 42 at a region, other than the region at which the output light is taken-out, of the surface 16a of the n-type GaN layer 16, which surface 16a is at the side at which the light emitting region 44 (see FIG. 5) is formed.

The fourth step is a step in which a Ti thin film and an Al thin film are vacuum vapor deposited on the region, other than the region where the output light is taken-out, of the surface 16a of the n-type GaN layer 16, and a heat treatment for forming ohmic contact is carried out for two minutes at 600° C. in a nitrogen gas atmosphere, and the n side electrode 42 is formed. Electrodes are formed by carrying out copper plating at via holes formed in the AlN sintered body substrate that is the supporting substrate 30 (illustration thereof is omitted).

Thereafter, next, electrolytic plating is carried out by using a copper plating liquid whose main component is copper sulfate, by using the p side electrode 26 as the seed electrode. Further, heat pipes (not illustrated) for heat dissipation are formed, and electrodes (not illustrated) are formed at the reverse surfaces of the heat pipes (surfaces at the side opposite the surface of the supporting substrate 30 joined with the p side electrode 26). Finally, dicing for making the LEDs into single LED chips is carried out.

The thermal conductivity of an Si substrate is 1.5 W/(cm K), and the resistivity thereof is 104 Ωmm. In contrast, the thermal conductivity of an AlN sintered body substrate is 2.5 W/(cm K), and the resistivity thereof is 109 Ωmm. Accordingly, in accordance with the LED fabricating method of the exemplary embodiment of the present invention, a GaN based LED can be fabricated that is provided with a supporting substrate of a material that has high thermal conductivity and high electric conductivity, and at which the surface area of the region for taking-out light can be made to be large.

<Structure of the LED of the Exemplary Embodiment of the Present Invention>

In accordance with the above-described LED fabricating method of the exemplary embodiment of the present invention, the LED of the present invention that is described below can be fabricated. The structure of the LED of the exemplary embodiment of the present invention is described with reference to FIG. 5. FIG. 5 is a drawing showing the cross-sectional structure of the LED of the exemplary embodiment of the present invention.

The LED of the present invention is structured to include the LED epitaxial growth layer 40-2, the p side electrode 26, the supporting substrate 30, the n side electrode 42, and the region 44 at which the output light is taken-out.

The LED epitaxial growth layer 40-2 is structured from the n-type GaN layer 16 and the epitaxial growth layer 20 that includes the InGaN light emitting layer 20-2. The detailed structures of the LED epitaxial growth layer 40-2 and the epitaxial growth layer 20 are as shown in FIGS. 1A through 1C. The p side electrode 26 is formed at a reverse 16b of the surface 16a that is at the side, at which the output light is taken-out, of the n-type GaN layer 16. Further, the p side electrode 26 and the supporting substrate 30 are joined by surface-activated room-temperature bonding joining, and the n side electrode 42 is formed at the region, other than the region 44 at which the output light is taken-out, of the surface 16a of the n-type GaN layer 16 at the side at which the output light is taken-out. Via holes 38 are formed in the AlN sintered supporting substrate 30 that is the supporting substrate 30. Moreover, a p side electrode 28 is formed at a reverse 30b of the surface, of the AlN sintered supporting substrate 30, which surface is at the side at which the LED epitaxial growth layer 40-2 is joined.

What is claimed is:

1. A light emitting diode fabricating method comprising:
a) forming, on a substrate and via a buffer layer, an epitaxial growth layer that includes a light emitting layer, and forming one electrode on a surface of the epitaxial growth layer;
b) joining a supporting substrate to the one electrode;
c) removing, by etching, the substrate and the buffer layer; and
d) forming another electrode at a region, other than a region where output light is taken-out, at a reverse surface opposite the surface of the epitaxial growth layer on which the one electrode is formed.

2. The light emitting diode fabricating method of claim 1, wherein the joining is carried out by a surface-activated room-temperature bonding joining method that joins a surface of the one electrode and a surface of the supporting substrate by a surface activating treatment that puts atoms of the surfaces into an active state.

3. The light emitting diode fabricating method of claim 1, wherein
the forming of the epitaxial growth layer and the one electrode includes forming, on an n-type Si substrate, the buffer layer that includes an AlN nucleation layer, an AlGaN layer and a GaN/AlN multilayer buffer layer, and an n-type GaN layer, and the epitaxial growth layer that includes an InGaN light emitting layer, and forming a p side electrode as the one electrode on the surface of the epitaxial growth layer,
the joining includes joining the supporting substrate to the p side electrode,
the removing includes removing, by etching, the n-type Si substrate and the buffer layer, and
the forming the other electrode includes forming an n side electrode as the other electrode at a region other than a region where output light is taken-out of a reverse surface opposite a surface, of the n-type GaN layer, which surface is at a side where the epitaxial growth layer including the InGaN light emitting layer is formed.

4. The light emitting diode fabricating method of claim 3, wherein an AlN sintered supporting substrate is used as the supporting substrate.

5. The light emitting diode fabricating method of claim 3, wherein a copper supporting substrate is used as the supporting substrate.

6. The light emitting diode fabricating method of claim 4, wherein an AlN sintered supporting substrate, in which via holes are formed, is used as the AlN sintered supporting substrate.

7. A light emitting diode comprising:
an epitaxial growth layer that includes a light emitting layer; and
a supporting substrate joined to a surface of an electrode formed at the epitaxial growth layer.

8. The light emitting diode of claim 7, wherein
the light emitting layer is an InGaN light emitting layer, and the epitaxial growth layer is structured from an epitaxial growth layer that includes an n-type GaN layer and the InGaN light emitting layer,
a p side electrode is formed on a reverse surface opposite a surface, of the n-type GaN layer, which surface is at a side where output light is taken-out, and
the p side electrode and the supporting substrate are joined by surface-activated room-temperature bonding joining, and an n side electrode is formed at a region, other than a region where the output light is taken-out, of the surface of the n-type GaN layer at the side where the output light is taken-out.

9. The light emitting diode of claim 7, wherein the supporting substrate is an AlN sintered supporting substrate.

10. The light emitting diode of claim 7, wherein the supporting substrate is a copper supporting substrate.

11. The light emitting diode of claim 9, wherein via holes are formed in the AlN sintered supporting substrate.
